(19) United States
(12) Patent Application Publication
(10) Pub. No.: US 2016/0077160 A1
(43) Pub. Date: Mar. 17, 2016

(54) BATTERY IMPEDANCE AND POWER CAPABILITY ESTIMATOR AND METHODS OF MAKING AND USING THE SAME

(71) Applicant: GM Global Technology Operations LLC, Detroit, MI (US)

(72) Inventors: Charles W. Wampler, II, Birmingham, MI (US); Daniel R. Baker, Romeo, MI (US); Mark W. Verbrugge, Troy, MI (US); Patrick Frost, Berkley, MI (US); Brian J. Koch, Berkley, MI (US); Patricia M. Laskowsky, Ann Arbor, MI (US)

(21) Appl. No.: 14/488,906

(22) Filed: Sep. 17, 2014

(51) Int. Cl. G01R 31/36

(52) U.S. Cl. CPC G01R 31/3662; G01R 31/3648

(57) ABSTRACT

A number of illustrative variations may include a method, which may include using at least a segment of impedance-based battery power capability estimation data, and using real-time linear regression, which may be used as a method of estimating future behavior of a system based on current and previous data points, to provide a robust state of power predictor.

### TECHNICAL FIELD

The field to which the disclosure generally relates to includes battery estimators and methods of making and using the same.

### BACKGROUND

Vehicles having a battery may use a battery property estimator.

### SUMMARY OF SELECT ILLUSTRATIVE VARIATIONS

A number of illustrative variations may include a method, which may include using at least a segment of impedance-based battery power capability estimation data, and using real-time linear regression, which may be used as a method of estimating future behavior of a system based on current and previous data points, to provide a robust state of power predictor. Linear regression may be performed by forming an RC circuit which is equivalent to electrochemical impedance spectroscopy data and processing the runtime values of that RC circuit using any number of known real-time linear regression algorithms which may include, but are not limited to, a weighted recursive least squares (WRLS) algorithm, Kalman filter algorithm or other means.

A number of illustrative variations may include a method comprising: using a controller and any number of sensors to obtain impedance data from a battery at a number of battery temperatures and battery states of charge; building an equivalent R+N(R∥C) or R∥(R+C)^{N} circuit which operates in a manner approximating the obtained impedance data; determining at least one of the power capabilities of the equivalent circuit by use of domain matrix exponentials, a Laplace transform, a Fourier transform, a Fourier series, or any other method of integrating a system of ordinary differential equations; and, estimating at least one of the power capabilities of the battery based upon at least one of the determined power capabilities of the equivalent circuit.

Other illustrative variations within the scope of the invention will become apparent from the detailed description provided hereinafter. It should be understood that the detailed description and specific examples, while disclosing variations within the scope of the invention, are intended for purposes of illustration only and are not intended to limit the scope of the invention.

### BRIEF DESCRIPTION OF THE DRAWINGS

Select examples of variations within the scope of the invention will become more fully understood from the detailed description and the accompanying drawings, wherein:

FIG. 1A illustrates a circuit including a resistor in parallel with N R+C pairs according to a number of variations.

FIG. 1B illustrates a circuit including a resistor in series with N R∥C pairs according to a number of variations.

### DETAILED DESCRIPTION OF ILLUSTRATIVE VARIATIONS

The following description of the variations is merely illustrative in nature and is in no way intended to limit the scope of the invention, its application, or uses.

In a number of illustrative variations a battery, a control system which may comprise at least one controller, and any number of sensors may be provided. The sensors may be may be capable of detecting one or more conditions which may include but are not limited to sound, pressure, temperature, acceleration, state of battery charge, state of battery power, current, voltage or magnetism and may be capable of producing at least one of sensor data or sensor signals and may sense and be at least one of polled or read by a control system. In such variations the control system and any number of sensors may be used to obtain impedance data from a battery at a number of battery temperatures and battery states of charge. Based at least upon obtained impedance data, an equivalent R+N(R∥C) or R∥(R+C)^{N} circuit which operates in a manner approximating the obtained battery impedance data may be constructed by first determining a relation of battery current to battery voltage over a period of time, and solving for a necessary number and value of each equivalent circuit component in adherence with a predetermined current voltage relation. In such variations, the control system may be used to determine at least one of the power capabilities of the equivalent circuit by use of differential equations, domain matrix exponentials, Laplace transform(s), Fourier transform(s), Fourier series, or any method of integrating a system of ordinary differential equations. Lastly, the control system may be used to determine at least one of the power capabilities of the battery based upon at least one of the determined power capabilities of the equivalent circuit.

In a number of illustrative variations, the necessary number and value of each equivalent circuit component is determined by a real-time state estimator.

In a number of illustrative variations, a real-time state estimator maintains an estimate of the equivalent circuit's present resistor and capacitor values, Rᵢ and Cᵢ, respectively, and the equivalent circuit open-circuit voltage, V₀.

In a number of illustrative variations, impedance data may be processed using any number of linear regression methods which may include but are not limited to the use of a Kalman filter, WRLS analysis, or any other method known in the art. In such variations, the equivalent circuit may be constructed to operate in a manner approximating the processed data.

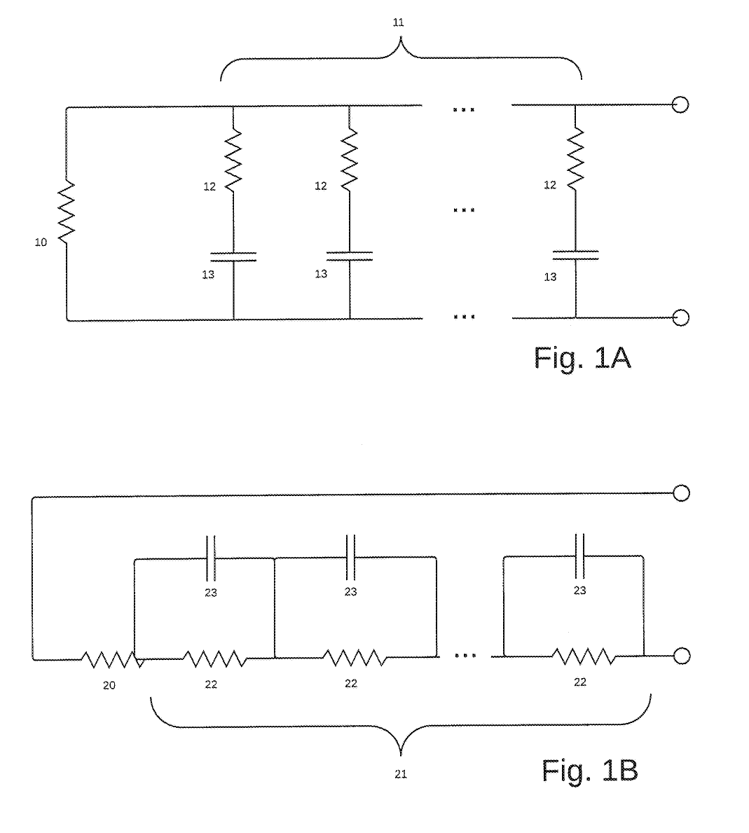

In a number of illustrative variations, and as illustrated by FIG. 1A, the equivalent circuit constructed to operate in a manner approximating the processed data consists of a resistor 10 in parallel with any number of R+C pairs 11. Each of the R+C pairs consists of a resistor 12 in series with a capacitor 13. It is understood that the values of the resistors and capacitors in 11 are not expected to be equal.

In a number of illustrative variations, and as illustrated by FIG. 1B, the equivalent circuit is constructed to operate in a manner approximating the processed data consists of a resistor 20 in series with any number of R∥C pairs 21. Each of the R∥C pairs consists of a resistor 22 in series with a capacitor 23. It is understood that the values of the resistors and capacitors in 21 are not expected to be equal.

In a number of illustrative variations, the battery yielding the processed data upon which the equivalent circuit is based may have voltage and current limits. In such variations, for the sake of avoiding damage to the battery, power predictions for the battery may be made by holding the equivalent circuit current at an extreme constant value and determining whether the resultant circuit voltage will remain within the voltage limits of the battery. If it is determined that the circuit voltage will remain within the voltage limits of the battery, a current-limited power may be predicted for the battery based on the extreme constant current. If, it is determined that the circuit voltage will not remain within the voltage limits of the battery, then the circuit voltage may be held at an extreme constant value within the battery voltage limits, and the current corresponding to the extreme constant voltage may then be determined. A voltage-limited power may then be predicted for the battery based on the extreme circuit voltage.

In a number of illustrative variations, the current or voltage of the system may held at a constant extreme, and a Fourier series, a Fourier transform, or Laplace transform may be used in conjunction with a predetermined current voltage relationship of the equivalent circuit to solve for the battery power at time t.

In a number of illustrative variations where the equivalent circuit is in the form of an R+N(R∥C) circuit and input voltage, V is held at an extreme constant, the known open circuit voltage, V₀ may be used with the circuit overpotential, V₁ to solve for the equivalent circuit current and power at time, t. In such variations, the ordinary differential equation (ODE) system is

$$\frac{d {v}_{i}}{d t} = \frac{1}{{C}_{i}} [ I - \frac{1}{{R}_{i}} {v}_{i} ] , i = 1 , … , N$$

and the overpotential, V₁ can be determined according to

V₁=IR+v₁+ . . . +v_{N}

In a number of illustrative variations, for the purpose of determining the power capabilities of an R+N(R∥C) circuit, it may be assumed that input current, I is held constant at an extreme (allowable, insofar as the cell is not damaged) value for a chosen interval, t seconds. In such variations, assuming N R∥C pairs, voltage across capacitor i, Cᵢ at time, t may be solved for according to

$${v}_{i} ( t ) = v ( 0 ) exp ( \frac{- t}{{R}_{i} {C}_{i}} ) + {IR}_{i} ( 1 - exp ( \frac{- t}{{R}_{i} {C}_{i}} ) )$$

and power at time, t may be predicted according to

Power(t)=I(V₀+IR+v₁(t)+ . . . +V_{N}(t))

In a number of illustrative variations where the equivalent circuit is in the form of an R+N(R∥C) circuit and input voltage, V is held at an extreme constant, the power of the equivalent circuit at time, t may be solved for using a Laplace transform. Using the Laplace transform of the ODE system of an R+N(R∥C) circuit, above, combined with the equation for overpotential, V₁, above, a transfer function for voltage to current of an R+N(R∥C) equivalent circuit, as well as the impedance of the circuit, Z(s), may be written as

$$V ( s ) = \frac{{\tilde{V}}_{1} ( s )}{\tilde{I} ( s )} = R + \frac{1 / {C}_{1}}{( s + 1 ) / {R}_{1} {C}_{1}} + … + \frac{1 / {C}_{N}}{( s + 1 ) / {R}_{N} {C}_{N}}$$

where \tilde{V}₁ is the Laplace transform of the overpotential, V₁ and Ĩ is the Laplace transform of the current, I. The admittance of the circuit may then be expressed as

$$A ( s ) = \frac{\tilde{I} ( s )}{{\tilde{V}}_{1} ( s )} = \frac{1}{Z ( s )}$$

To get the admittance in partial fraction form, the impedance, Z(s) must be written as a ratio of two polynomials by placing all the fractions over a common denominator:

$$Z ( s ) = \frac{R ( s + {b}_{1} ) … ( s + {b}_{N} ) + {a}_{1} {p}_{1} ( s ) + … + {a}_{N} {p}_{N} ( s )}{( s + {b}_{1} ) … ( s + {b}_{N} )} {=}^{def} \frac{RQ ( s )}{P ( s )}$$

where P(s) and Q(s) are defined by this expression and where

$${p}_{i} ( s ) = \frac{Q ( s )}{s + {b}_{i}} = {\prod }_{\begin{matrix}j = 1 , … , N \\ j \neq i\end{matrix}} ( s + {b}_{j} )$$

All of the products may then be expanded to write Q(s) as an N-th order polynomial:

Q(s)=s^{N}+α₁s^{N-1}+ . . . +α_{N-1}s+α_{N}

the admittance transfer function may then be written as

$$A ( s ) = \frac{\tilde{I} ( s )}{{\tilde{V}}_{1} ( s )} = \frac{1}{Z ( s )} = \frac{P ( s )}{RQ ( s )}$$

To put this in partial fraction form, Q(s) is factored:

Q(s)=(s+r₁) . . . (s+r_{N})

Note that for N=1, Q(s) is already factored; for N=2, Q(s) can be factored using the quadratic formula; and, for N>2, Q(s) can be factored by using any of several well-known techniques, such as applying a standard eigenvalue routine to find the eigenvalues of the companion matrix to Q(s), which is an N×N matrix having 1 in each entry of the superdiagonal and last row equal to [−α_{N} . . . α₁]. Then r₁, . . . , r_{N} in the factored form of Q(s) above are the negatives of the eigenvalues the companion matrix. The partial fraction form of the admittance transform function may be expressed as

$$A ( s ) = \frac{\tilde{I} ( s )}{{\tilde{V}}_{1} ( s )} = ( \frac{1}{R} ) ( 1 + \frac{{A}_{1}}{s + {r}_{1}} + … + \frac{{A}_{N}}{s + {r}_{N}} )$$

where the constants Aᵢ can be evaluated using the formula

$${A}_{i} = \frac{P ( - {r}_{i} )}{{q}_{i} ( - {r}_{i} )} , \\ with$$

$${q}_{i} ( s ) {=}^{def} {\prod }_{\begin{matrix}j = 1 , … , N \\ j \neq i\end{matrix}} ( s + {r}_{j} )$$

Assuming a constant overpotential V₁, this admittance formula implies that the time evolution of I(t) is of the form

$$I ( t ) = \frac{{V}_{1}}{R} ( 1 + \frac{{A}_{1}}{{r}_{1}} ( 1 - {e}^{- {r}_{1} t} ) + … + \frac{{A}_{N}}{{r}_{N}} ( 1 - {e}^{- {r}_{N} t} ) ) + \frac{1}{R} ( {K}_{1} {e}^{- {r}_{1} t} + … + {K}_{N} {e}^{- {r}_{N} t} )$$

Where K₁, . . . , K_{N} must be determined to match the initial conditions. Kᵢ may be determined by matching the initial value of I(0) and its first (N−1) time derivatives as given by the equation for current above in conjunction with the ODE system for an R+N(R∥C) circuit above. This matching must hold for any value of V₁, so it may be assumed that V₁=0. The matching condition is a system of linear equations:

(−r₁)^{j}K₁+ . . . +(−r_{N})^{j}K_{N}=−[1 . . . 1]A^{j}v(0), j=0, . . . , N−1

where A is the N×N matrix which may be derived from the ODE system for an R+N(R∥C) circuit above, and A⁰=I_{N}, A¹=A, A²=A*A, etc., and I_{N} is an N×N identity matrix. This system of N linear equations in N unknowns can be solved using standard techniques of numerical linear algebra, such as Gaussian elimination with pivoting. With the Kᵢ determined, I(t) may be evaluated at time t using the equation for current above, and the power at time t for constant overpotential, V₁ is

Power(t)=(V₀+V₁)I(t)

In a number of illustrative variations where the equivalent circuit is in the form of an R+N(R∥C) circuit and input voltage, V is held at an extreme constant, the power of the equivalent circuit at time t may be solved for using a matrix exponential. Imposing a constant voltage at an extreme implies a constant overpotential voltage

V₁=V−V₀

Applying a constant overpotential, V₁ for t seconds, it can be inferred from the equation for overpotential, above, that the current is

I=[V₁−(v₁(t)+ . . . +v_{N}(t))]/R

Substituting this into the ODE system for an R+N(R∥C) circuit above gives

$$\frac{d {v}_{i}}{d t} = \frac{1}{{C}_{i}} [ \frac{1}{R} ( {V}_{1} - {v}_{1} - ⋯ - {v}_{N} ) - \frac{1}{{R}_{i}} {v}_{i} ] , i = 1 , … , N$$

This can be put into matrix form as

$$\frac{d}{d t} v = Av + {BV}_{1}$$

where

$$[ \begin{matrix}{v}_{1} ( t ) \\ ⋮ \\ {v}_{N} ( t )\end{matrix} ] ,$$

and the entries in the N×N matrix A and the N×1 matrix B are in accordance with the ODE system for an R+N(R∥C) circuit, above. The solution of this ODE for constant V₁ is

v(t)=exp(At)v(0)+A⁻¹(exp(At)−I_{N})BV₁

where A⁻¹ is the matrix inverse of A, I_{N} is an N×N identity matrix, and exp( ) is the matrix exponential function which may be evaluated in a number of ways known in the art. After evaluating v(t), the power at time t is found as

$$Power ( t ) = ( {V}_{0} + {V}_{1} ) ( \frac{1}{R} ( {V}_{1} - [ 1 ⋯ 1 ] v ( t ) ) )$$

In a number of illustrative variations where the equivalent circuit is in the form of an R+N(R∥C) circuit and input voltage, V is held at an extreme constant, the vector of voltages, v(t), for the equivalent circuit at time t may be solved for using a well-known numerical integration methods such as but not limited to the Runge-Kutta method, the Adams-Bashforth method, and the Euler method. In such illustrative variations, once v(t) has been found at time t, the power at time t can be evaluated using the power equation found in the illustrative variation utilizing the matrix exponential for an R+N(R∥C) circuit, above.

In a number of illustrative variations where the equivalent circuit is in the form of an R∥(R+C)^{N} circuit and input current, I is held at an extreme constant, the known input current I may be used with the circuit overpotential V₁ to solve for the equivalent circuit current and power at time t. In such variations, the ordinary differential equation (ODE) system is

$$\frac{d}{d t} {v}_{i} = ( {V}_{1} - {v}_{i} ) \frac{1}{{R}_{i} {C}_{i}} , i = 1 , … , N$$

and the overpotential V₁ can be determined according to

$${V}_{1} = {( \frac{1}{R} + \frac{1}{{R}_{1}} + ⋯ + \frac{1}{{R}_{N}} )}^{- 1} ( I + \frac{{v}_{1}}{{R}_{1}} + ⋯ + \frac{{v}_{N}}{{R}_{N}} )$$

In a number of illustrative variations, for the purpose of determining the power capabilities of an R∥(R+C)^{N} circuit, it may be assumed that the input voltage, V is held constant at an extreme value for a chosen interval t seconds. In such variations, assuming N R+C pairs, voltage across capacitor Cᵢ at time t may be solved for according to

$${v}_{i} ( t ) = {v}_{i} ( 0 ) exp ( \frac{- t}{{R}_{i} {C}_{i}} ) + {V}_{1} ( 1 - exp ( \frac{- t}{{R}_{i} {C}_{i}} ) ) , i = 1 , … , N$$

and power at time t may be predicted according to

Power(t)=(V₀+V₁(t))I

In a number of illustrative variations where the equivalent circuit is in the form of an R∥(R+C)^{N} circuit and input current, I is held at an extreme constant, the power of the equivalent circuit at time, t may be solved for using a Laplace transform. Using the Laplace transform of the ODE system of an R∥(R+C)^{N} circuit, above, combined with the equation for overpotential, V₁, above, a transfer function for voltage to current of an R∥(R+C)^{N} equivalent circuit, as well as the admittance of the circuit, A(s), may be written as

$$A ( s ) = \frac{\tilde{I} ( s )}{{\tilde{V}}_{1} ( s )} = \frac{1}{R} + \frac{{C}_{1} s}{{R}_{1} {C}_{1} s + 1} + ⋯ + \frac{{C}_{N} s}{{R}_{N} {C}_{N} s + 1}$$

where \tilde{V}₁ is the Laplace transform of the overpotential, V₁ and Ĩ is the Laplace transform of the current, I. Being the reciprocal of the circuit impedance, admittance of the circuit may also be expressed as

$$A ( s ) = \frac{aQ ( s )}{P ( s )}$$

where a is a scalar chosen to make the leading term in Q(s) to be s^{N}, (i.e., the leading coefficient is 1). The partial fraction form of the impedance transform function may then be obtained:

$$Z ( s ) = \frac{\tilde{{\tilde{V}}_{1} ( s )}}{\tilde{I} ( s )} = ( \frac{1}{a } ) ( 1 + \frac{{Z}_{1}}{s + {r}_{1}} + ⋯ + \frac{{Z}_{N}}{s + {r}_{N}} )$$

Where the constants Zᵢ can be evaluated using the formula

$${Z}_{i} = \frac{P ( - {r}_{i} )}{{{q}_{i} ( - {r}_{i} )}^{′}} with {q}_{i} ( s ) {=}^{def} {\prod }_{{j = 1 , … , N}_{j \neq i}} ( s + {r}_{j} )$$

For constant V₁, this admittance formula implies that the time evolution of V₁(t) is of the form

$${V}_{1} ( t ) = \frac{1}{a} ( 1 + \frac{{Z}_{1}}{{r}_{1}} ( 1 - {e}^{- {r}_{1} t} ) + ⋯ + \frac{{Z}_{N}}{{r}_{N}} ( 1 - {e}^{- {r}_{N} t} ) ) + \frac{1}{a} ( {K}_{1} {e}^{- {r}_{1} t} + ⋯ + {K}_{N} {e}^{- {r}_{N} t} )$$

Where K₁, . . . , K_{N} must be determined to match the initial conditions. Kᵢ may be determined by matching the initial value of I(0) and its first (N−1) time derivatives as given by the equation for current above in conjunction with the ODE system for an R∥(R+C)^{N} circuit above. This matching must hold for any value of I, so it may be assumed that I=0. The matching condition is a system of linear equations:

(−r₁)^{j}K₁+ . . . +(−r_{N})^{j}K_{N}=−[1 . . . 1]A^{j}v(0), j=0, . . . ,N−1

where A is the N×N matrix which may be derived from the ODE system for an R∥(R+C)^{N} circuit above, and A⁰=I_{N}, A¹=A, A²=A*A, etc., and I_{N} is an N×N identity matrix. This system of N linear equations in N unknowns can be solved using standard techniques of numerical linear algebra, such as Gaussian elimination with pivoting. With the Kᵢ determined, V₁(t) may be evaluated at time t using the equation for overpotential above, and the power at time t for constant current, I is

Power(t)=(V₀+V₁(t))I

In a number of illustrative variations where the equivalent circuit is in the form of an R∥(R+C)^{N} circuit and input current, I is held at an extreme constant, the power of the equivalent circuit at time t may be solved for using a matrix exponential. Knowing that the total current flowing through an equivalent circuit in the form of an R∥(R+C)^{N} circuit is

$$I = \frac{{V}_{1}}{R} + \frac{{V}_{1} - {v}_{1}}{{R}_{1}} + ⋯ + \frac{{V}_{1} - {v}_{N}}{{R}_{N}}$$

it can then be inferred that the equation for overpotential V₁ is

$${V}_{1} = {( \frac{1}{R} + \frac{1}{{R}_{1}} + ⋯ + \frac{1}{{R}_{N}} )}^{- 1} ( I + \frac{{v}_{1}}{{R}_{1}} + ⋯ + \frac{{v}_{N}}{{R}_{N}} )$$

This may be substituted into the ODE system for an R∥(R+C)^{N} circuit above and written in matrix form as

$$\frac{d}{d t} v = Av + BI$$

Where

$$v = [ \begin{matrix}{v}_{1} ( t ) \\ ⋮ \\ {v}_{N} ( t )\end{matrix} ] ,$$

and the entries in the N×N matrix A and the N×1 matrix B are in accordance with the ODE system for an R∥(R+C)^{N} circuit, above. The solution of this ODE for constant I is

v(t)=exp(At)v(0)+A⁻¹(exp(At)−I_{N})BI

where A⁻¹ is the matrix inverse of A, I_{N} is an N×N identity matrix, and exp( ) is the matrix exponential function which may be evaluated in a number of ways known in the art. After evaluating v(t), V₁(t) may be solved for using the N×1 matrix v according to

$${V}_{1} ( t ) = {( \frac{1}{R} + \frac{1}{{R}_{1}} + ⋯ + \frac{1}{{R}_{N}} )}^{- 1} ( I + \frac{{v}_{1} ( t )}{{R}_{1}} + ⋯ + \frac{{v}_{N} ( t )}{{R}_{N}} )$$

The power at time t may then be found:

Power(t)=(V₀+V₁(t))I

In a number of illustrative variations where the equivalent circuit is in the form of an R∥(R+C)^{N} circuit and input current is held at an extreme constant, the vector of voltages, v(t), for the equivalent circuit at time t may be solved for using a well-known numerical integration methods such as but not limited to the Runge-Kutta method, the Adams-Bashforth method, and the Euler method. In such illustrative variations, once v(t) has been found at time t, the power at time t can be evaluated using the power equation found in the illustrative variation utilizing the matrix exponential for an R∥(R+C)^{N} circuit, above.

In a number of illustrative variations, once the desired voltage current relationship of the equivalent circuit is known, the necessary value of equivalent circuit components may be derived therefrom using a number of methods such as but not limited to manipulation of the voltage current relationship via a Laplace transform or Fourier transform. As a non-limiting example, a desired current voltage relationship for an equivalent R+N(R∥C) circuit may be described in the time domain and of the form

i(t)=∫₀^{t}K(t−τ)[V(τ)−V₀]dτ given that V(t)−V₀=i(t)=0 for t≦0 a)

and necessary values for the components needed to build an equivalent circuit may be determined by setting a Fourier transform of the equivalent circuit impedance, Z(ω), equivalent to battery impedance data spectra, where the non-transformed R+N(R∥C) circuit impedance is

$$Z = R + {\sum }_{i = 1}^{N} \frac{{R}_{i}}{1 + jω {R}_{i} {C}_{i}}$$

with the Fourier transform of the equivalent circuit impedance being

$$Z ( ω ) = R \frac{{A}_{N + 1} = jω {A}_{N + 2} + ⋯ + {( jω )}^{N - 1} {A}_{2 N} + {( jω )}^{N}}{{A}_{1} + jω {A}_{2} + ⋯ + {( jω )}^{N - 1} {A}_{N} + {( jω )}^{N}}$$

and where

$$A ( ω ) = \frac{1}{Z ( ω )} so that \tilde{i} ( ω ) = A ( ω ) [ \tilde{V} ( ω ) - {\tilde{V}}_{0} ]$$

and also where

$$A ( ω ) = \frac{{A}_{1} + {A}_{2} jω + ⋯ + {( jω )}^{N}}{R ( jω - {α}_{1} ) ( jω - {α}_{2} ) … ( jω - {α}_{N} )}$$

in which αᵢ are roots of the polynomial from equation c), and the equivalent circuit resistor and capacitor values may be solved for by relating the solved coefficients A₁, A₂, . . . A_{N} of equation e) to

$${A}_{1} + {A}_{2} jω + ⋯ + {A}_{N} {jω}^{N - 1} + {jω}^{N} = {\prod }_{i = 1}^{N} ( jω + \frac{1}{{R}_{i} {C}_{i}} ) = P ( jω )$$

A number of variations may include a method including using a state of power predictor comprising a RC circuit which is modeled based on impedance spectroscopy data from an energy storage device such as but not limited to a battery, supercapacitor or other electrochemical device and processing the runtime values of that RC circuit using any number of known real-time linear regression algorithms including, but not limited, to a weighted recursive least squares (WRLS), Kalman filter or other means. The method may also include a controller constructed and arranged to receive input from the state of power predictor, compare the input from the predictor with predetermined values and take action such as send a signal representative of the predicted state of power or take other action when the input from the predictor is within a predetermined range of the predetermined values. In a number of variations the controller may be constructed and arranged to prevent a particular usage of a battery based upon the state of power prediction.

The following description of variants is only illustrative of components, elements, acts, products and methods considered to be within the scope of the invention and are not in any way intended to limit such scope by what is specifically disclosed or not expressly set forth. The components, elements, acts, products and methods as described herein may be combined and rearranged other than as expressly described herein and still are considered to be within the scope of the invention.

Variation 1 may include a method comprising: obtaining impedance data from a battery; building an equivalent circuit which operates in a manner approximating the battery impedance data; determining at least one of the power capabilities of the equivalent circuit; and, estimating at least one of the power capabilities of the battery based upon the determined power capabilities of the equivalent circuit.

Variation 2 may include a method as set forth in claim 1 wherein the impedance data is obtained at a number of battery temperatures and states of charge.

Variation 3 may include a method as set forth in claim 1 wherein the equivalent circuit is an R+N(R∥C) circuit.

Variation 4 may include a method as set forth in variation 3 wherein estimating at least one of the power capabilities of the battery based upon the power capabilities of the equivalent circuit comprises: imposing a constant input current, I upon the equivalent circuit; solving for the voltage vᵢ(t), across capacitor Cᵢ, according to

$${v}_{i} ( t ) = v ( 0 ) exp ( \frac{- t}{{R}_{i} {C}_{i}} ) + I {R}_{i} ( 1 - exp ( \frac{- t}{{R}_{i} {C}_{i}} ) ) , i = 1 , … , N ;$$

predicting an equivalent circuit power at time, t according to

Power(t)=I(V₀+IR+v₁(t)+ . . . +v_{N}(t)); and,

correlating the equivalent circuit power at time, t to the power of the battery at time t.

Variation 5 may include a method as set forth in variation 3 wherein estimating at least one of the power capabilities of the battery based upon the power capabilities of the equivalent circuit comprises: imposing a an extreme constant input voltage, V upon the equivalent circuit; using a Laplace transform of the circuit impedance to formulate an equation for the time evolution of the equivalent circuit current I(t); solving for an equivalent circuit current at time t by assuming a constant overpotential for the equivalent circuit; solving for an equivalent circuit power at time t via the equation:

Power(t)=(V₀+V₁)I(t); and,

correlating the equivalent circuit power at time, t to the power of the battery at time t.

Variation 6 may include a method as set forth in variation 3 wherein estimating at least one of the power capabilities of the battery based upon the power capabilities of the equivalent circuit comprises: imposing an extreme constant input voltage, V upon the equivalent circuit; assuming a constant overpotential V₁; estimating the equivalent circuit power at time t via the use of matrix exponential to solve for the equivalent circuit voltage at time t, v(t):

v(t)=exp(At)v(0)+A⁻¹(exp(At)−I_{N})BV₁;

predicting the equivalent circuit power at time t according to

$$Power ( t ) = ( {V}_{0} + {V}_{1} ) ( \frac{1}{R} ( {V}_{1} - [ 1 ⋯ 1 ] v ( t ) ) ) ;$$

and,
correlating the equivalent circuit power at time, t to the power of the battery at time t.

Variation 7 may include a method as set forth in variation 3 wherein estimating at least one of the power capabilities of the battery based upon the power capabilities of the equivalent circuit comprises: imposing a constant input voltage, V upon the equivalent circuit; estimating the equivalent circuit power at time t via the use of known numerical integration methods and the equation:

$$Power ( t ) = ( {V}_{0} + {V}_{1} ) ( \frac{1}{R} ( {V}_{1} - [ 1 ⋯ 1 ] v ( t ) ) ) ;$$

and,
correlating the equivalent circuit power at time, t to the power of the battery at time t.

Variation 8 may include a method as set forth in variation 1 wherein the equivalent circuit is an R∥(R+C)^{N} circuit.

Variation 9 may include a method as set forth in variation 8 wherein estimating at least one of the power capabilities of the battery based upon the power capabilities of the equivalent circuit comprises: imposing a constant input voltage, V upon the equivalent circuit; assuming a constant overpotential V₁; solving for the voltage across capacitor Cᵢ, vᵢ(t) according to

$${v}_{i} ( t ) = {v}_{i} ( 0 ) exp ( \frac{- t}{{R}_{i} {C}_{i}} ) + {V}_{1} ( 1 - exp ( \frac{- t}{{R}_{i} {C}_{i}} ) ) , i = 1 , … , N ;$$

predicting an equivalent circuit power at time, t according to

Power(t)=(V₀+V₁(t))I; and,

correlating the equivalent circuit power at time, t to the power of the battery at time t.

Variation 10 may include a method as set forth in variation 8 wherein estimating at least one of the power capabilities of the battery based upon the power capabilities of the equivalent circuit comprises: imposing a an extreme constant input current, I upon the equivalent circuit; using a Laplace transform of the circuit impedance to formulate an equation for the time evolution of the equivalent circuit overpotential V₁(t); solving for an equivalent circuit current at time t by assuming a constant current for the equivalent circuit; solving for an equivalent circuit power at time t via the equation:

Power(t)=(V₀+V₁(t))I; and,

correlating the equivalent circuit power at time, t to the power of the battery at time t.

Variation 11 may include a method as set forth in variation 8 wherein estimating at least one of the power capabilities of the battery based upon the power capabilities of the equivalent circuit comprises: imposing an extreme constant input current, I upon the equivalent circuit; estimating the equivalent circuit power at time t via the use of matrix exponential to solve for the equivalent circuit voltage at time t, v(t):

v(t)=exp(At)v(0)+A⁻¹(exp(At)−I_{N})BI;

solving for V₁(t) according to

$${V}_{1} ( t ) = {( \frac{1}{R} + \frac{1}{{R}_{1}} + ⋯ + \frac{1}{{R}_{N}} )}^{- 1} ( I + \frac{{v}_{1} ( t )}{{R}_{1}} + ⋯ + \frac{{v}_{N} ( t )}{{R}_{N}} )$$

predicting the equivalent circuit power at time t according to

Power(t)=(V₀+V₁(t))I; and,

correlating the equivalent circuit power at time, t to the power of the battery at time t.

Variation 12 may include a method as set forth in variation 8 wherein estimating at least one of the power capabilities of the battery based upon the power capabilities of the equivalent circuit comprises: imposing a constant input current, I upon the equivalent circuit; estimating the equivalent circuit power at time t via the use of known numerical integration methods and the equation:

Power(t)=(V₀+V₁(t))I; and,

correlating the equivalent circuit power at time, t to the power of the battery at time t.

Variation 13 may include a method as set forth in variation 3 wherein building an equivalent circuit which operates in a manner approximating the battery impedance data comprises determining a relation of battery current to battery voltage over a period of time, and solving for a necessary number and value of each equivalent circuit component in adherence with a current voltage relation

i(t)=∫₀^{t}K(t−τ)[V(τ)−V₀]dτ given that V(t)−V₀=i(t)=0 for t≦0 a)

and solving for component values by setting a Fourier transform of the equivalent circuit impedance, Z(ω), equivalent to battery impedance data spectra, where the non-transformed RC circuit impedance is

$$Z = R + {\sum }_{i = 1}^{N} \frac{{R}_{i}}{1 + jω {R}_{i} {C}_{i}}$$

with the Fourier transform of the equivalent circuit impedance being

$$Z ( ω ) = R \frac{{A}_{N + 1} = jω {A}_{N + 2} + ⋯ + {( jω )}^{N - 1} {A}_{2 N} + {( jω )}^{N}}{{A}_{1} + jω {A}_{2} + ⋯ + {( jω )}^{N - 1} {A}_{N} + {( jω )}^{N}}$$

and where

$$A ( ω ) = \frac{1}{Z ( ω )} so that \tilde{i} ( ω ) = A ( ω ) [ \tilde{V} ( ω ) - {\tilde{V}}_{0} ]$$

and also where

$$A ( ω ) = \frac{{A}_{1} + {A}_{2} j ω + … + {( j ω )}^{N}}{R ( j ω - {α}_{1} ) ( j ω - {α}_{2} ) … ( j ω - {α}_{N} )}$$

in which αᵢ are roots of the polynomial from equation c), and the equivalent circuit resistor and capacitor values may be solved for by relating the solved coefficients A₁, A₂, . . . A_{N} of equation e) to

$${A}_{1} + {A}_{2} j ω + … + {A}_{N} j {ω}^{N - 1} + j {ω}^{N} = {Π}_{i = 1}^{N} ( j ω + \frac{1}{{R}_{i} {C}_{i}} ) = P ( jω )$$

The above description of select variations within the scope of the invention is merely illustrative in nature and, thus, variations or variants thereof are not to be regarded as a departure from the spirit and scope of the invention.

What is claimed is:

1. A method comprising:
obtaining impedance data from a battery;
building an equivalent circuit which operates in a manner approximating the battery impedance data;
determining at least one of the power capabilities of the equivalent circuit; and,
estimating at least one of the power capabilities of the battery based upon the determined power capabilities of the equivalent circuit.

2. A method as set forth in claim 1 wherein the impedance data is obtained at a number of battery temperatures and states of charge.

3. A method as set forth in claim 1 wherein the equivalent circuit is an R+N(R∥C) circuit.

4. A method as set forth in claim 3 wherein estimating at least one of the power capabilities of the battery based upon the power capabilities of the equivalent circuit comprises:
imposing a constant input current, I upon the equivalent circuit;
solving for the voltage, vᵢ(t) across capacitor Cᵢ, according to
$${v}_{i} ( t ) = v ( 0 ) exp ( \frac{- t}{{R}_{i} {C}_{i}} ) + {IR}_{i} ( 1 - exp ( \frac{- t}{{R}_{i} {C}_{i}} ) ) , i = 1 , … , N ;$$
predicting an equivalent circuit power at time, t according to
Power(t)=I(V₀+IR+v₁(t)+ . . . +V_{N}(t)); and
correlating the equivalent circuit power at time, t to the power of the battery at time t.

5. A method as set forth in claim 3 wherein estimating at least one of the power capabilities of the battery based upon the power capabilities of the equivalent circuit comprises:
imposing a an extreme constant input voltage, V upon the equivalent circuit;
using a Laplace transform of the circuit impedance to formulate an equation for the time evolution of the equivalent circuit current I(t);
solving for an equivalent circuit current at time t by assuming a constant overpotential for the equivalent circuit;
solving for an equivalent circuit power at time t via the equation:
Power(t)=(V₀+V₁)I(t); and,
correlating the equivalent circuit power at time, t to the power of the battery at time t.

6. A method as set forth in claim 3 wherein estimating at least one of the power capabilities of the battery based upon the power capabilities of the equivalent circuit comprises:
imposing an extreme constant input voltage, V upon the equivalent circuit;
assuming a constant overpotential V₁;
estimating the equivalent circuit power at time t via the use of matrix exponential to solve for the equivalent circuit voltage at time t, v(t):
v(t)=exp(At)v(0)+A⁻¹(exp(At)−I_{N})BV₁;
predicting the equivalent circuit power at time t according to
$$Power ( t ) = ( {V}_{0} - {V}_{1} ) ( \frac{1}{R} ( {V}_{1} - [ \begin{matrix}1 & … & 1\end{matrix} ] v ( t ) ) ) ;$$
and,
correlating the equivalent circuit power at time, t to the power of the battery at time t.

7. A method as set forth in claim 3 wherein estimating at least one of the power capabilities of the battery based upon the power capabilities of the equivalent circuit comprises:
imposing a constant input voltage, V upon the equivalent circuit;
estimating the equivalent circuit power at time t via the use of known numerical integration methods and the equation:
$$Power ( t ) = ( {V}_{0} - {V}_{1} ) ( \frac{1}{R} ( {V}_{1} - [ \begin{matrix}1 & … & 1\end{matrix} ] v ( t ) ) ) ;$$
and,
correlating the equivalent circuit power at time, t to the power of the battery at time t.

8. A method as set forth in claim 1 wherein the equivalent circuit is an R∥(R+C)^{N} circuit.

9. A method as set forth in claim 8 wherein estimating at least one of the power capabilities of the battery based upon the power capabilities of the equivalent circuit comprises:
imposing a constant input voltage, V upon the equivalent circuit;
assuming a constant overpotential V₁;
solving for the voltage across capacitor Cᵢ, vᵢ(t) according to
$${v}_{i} ( t ) = {v}_{i} ( 0 ) exp ( \frac{- t}{{R}_{i} {C}_{i}} ) + {V}_{1} ( 1 - exp ( \frac{- t}{{R}_{i} {C}_{i}} ) ) , i = 1 , … , N ;$$
predicting an equivalent circuit power at time, t according to
Power(t)=(V₀+V₁(t))I; and,
correlating the equivalent circuit power at time, t to the power of the battery at time t.

10. A method as set forth in claim 8 wherein estimating at least one of the power capabilities of the battery based upon the power capabilities of the equivalent circuit comprises:
imposing a an extreme constant input current, I upon the equivalent circuit;
using a Laplace transform of the circuit impedance to formulate an equation for the time evolution of the equivalent circuit overpotential V₁(t);
solving for an equivalent circuit current at time t by assuming a constant current for the equivalent circuit;
solving for an equivalent circuit power at time t via the equation:
Power(t)=(V₀+V₁(t))I; and,
correlating the equivalent circuit power at time, t to the power of the battery at time t.

11. A method as set forth in claim 8 wherein estimating at least one of the power capabilities of the battery based upon the power capabilities of the equivalent circuit comprises:
imposing an extreme constant input current, I upon the equivalent circuit;
estimating the equivalent circuit power at time t via the use of matrix exponential to solve for the equivalent circuit voltage at time t, v(t):
v(t)=exp(At)v(0)+A⁻¹(exp(At)−I_{N})BI;
solving for V₁(t) according to
$${V}_{1} ( t ) = {( \frac{1}{R} + \frac{1}{{R}_{1}} + … + \frac{1}{{R}_{N}} )}^{- 1} ( I + \frac{{v}_{1} ( t )}{{R}_{1}} + … + \frac{{v}_{N} ( t )}{{R}_{N}} )$$
predicting the equivalent circuit power at time t according to
Power(t)=(V₀+V₁(t))I; and,
correlating the equivalent circuit power at time, t to the power of the battery at time t.

12. A method as set forth in claim 8 wherein estimating at least one of the power capabilities of the battery based upon the power capabilities of the equivalent circuit comprises:
imposing a constant input current, I upon the equivalent circuit;
estimating the equivalent circuit power at time t via the use of known numerical integration methods and the equation:
Power(t)=(V₀+V₁(t))I; and,
correlating the equivalent circuit power at time, t to the power of the battery at time t.

13. A method as set forth in claim 3 wherein building an equivalent circuit which operates in a manner approximating the battery impedance data comprises determining a relation of battery current to battery voltage over a period of time, and solving for a necessary number and value of each equivalent circuit component in adherence with a current voltage relation
i(t)=∫₀^{t}K(t−τ)[V(τ)−V₀]dτ given that V(t)−V₀=i(t)=0 for t≦0 g)
and solving for component values by setting a Fourier transform of the equivalent circuit impedance, Z(ω), equivalent to battery impedance data spectra, where the non-transformed RC circuit impedance is
$$Z = R + {\sum }_{i = 1}^{N} \frac{{R}_{i}}{1 + j ω {R}_{i} {C}_{i}}$$
with the Fourier transform of the equivalent circuit impedance being
$$Z ( ω ) = R \frac{{A}_{N + 1} + j ω {A}_{N + 2} + … + {( j ω )}^{N - 1} {A}_{2 N} + {( j ω )}^{N}}{{A}_{1} + j ω {A}_{2} + … + {( j ω )}^{N - 1} {A}_{N} + {( jω )}^{N}}$$
and where
$$A ( ω ) = \frac{1}{Z ( ω )} so that \tilde{1} ( ω ) = A ( ω ) [ \tilde{V} ( ω ) - {\tilde{V}}_{0} ]$$
and also where
$$A ( ω ) = \frac{{A}_{1} + {A}_{2} j ω + … + {( j ω )}^{N}}{R ( j ω - {α}_{1} ) ( j ω - {α}_{2} ) … ( jω - {α}_{N} )}$$
in which αᵢ are roots of the polynomial from equation c), and the equivalent circuit resistor and capacitor values may be solved for by relating the solved coefficients A₁, A₂, . . . A_{N} of equation e) to
$${A}_{1} + {A}_{2} j ω + … + {A}_{N} j {ω}^{N - 1} + j {ω}^{N} = {Π}_{i = 1}^{N} ( j ω + \frac{1}{{R}_{i} {C}_{i}} ) = P ( j ω )$$
